(19) United States
(12) Patent Application Publication
(10) Pub. No.: US 2008/0089113 A1
(43) Pub. Date: Apr. 17, 2008

(54) Organic-Complex Thin Film For Nonvolatile Memory Applications

(75) Inventors: Yang Yang, Los Angeles, CA (US); Jianyong Ouyang, Los Angeles, CA (US); Chih-Wei Chu, Taipei City (TW)

Correspondence Address: VENABLE LLP, P.O. BOX 34385, WASHINGTON, DC, 20043-9998, US

(73) Assignee: The Regents of the University of California, Oakland, CA (US)

(21) Appl. No.: 11/666,303

(22) PCT Filed: Oct. 27, 2005
(86) PCT No.: PCT/US05/38849

§ 371 Date: Apr. 26, 2007

Related U.S. Application Data
(60) Provisional application No. 60/623,721, filed on Oct. 28, 2004.

(51) Int. Cl. G11C 11/00; H01B 1/12

(52) U.S. Cl. 365/153; 252/500

(57) ABSTRACT

An electronic or electro-optic device according to an embodiment of this invention has a first electrode, a second electrode spaced apart from the first electrode, and an organic composite layer disposed between the first electrode and the second electrode. The organic composite layer is composed of an electron donor material, an electron acceptor material, and a polymer matrix material. The organic composite layer exhibits substantial bistability of an electrical property.

### CROSS-REFERENCE OF RELATED APPLICATION

This application claims priority to U.S. Provisional Application No. 60/623,721 filed Oct. 28, 2004, the entire contents of which are hereby incorporated by reference.

### BACKGROUND

1. Field of Invention

The present invention relates to an organic composite material having bistability of an electrical property, electronic or electro-optic devices having the organic composite material and methods of use.

2. Discussion of Related Art

In recent years, organic electronic devices have been replacing inorganic-dominated electronic and opto-electronic devices, such as light emitting diodes C. W. Tang and S. A. VanSlyke, Appl. Phys. Lett. 51, 913, (1987), R. H. Friend, R. W. Gymer, A. B. Holmes, J. H. Burroughes, R. N. Marks, C. Taliani, D. D. C. Bradley, D. A. Dos Santos, J. L. Bredas, M. Logdlund, and W. R. Salaneck, Nature 397, 121 (1999), solar cells N. S. Sariciftci, L. Smilowitz, A. J. Heeger and F. Wudl, Science 258, 1474 (1992), and transistors D. J. Gundlach, Y. Y. Lin, T. N. Jackson, S. F. Nelson, and D. G. Schlom, IEEE Electron Device Lett. 18, 87 (1997), due to the extraordinary advantages of organic materials. One of the primary appeals of organic materials is fabricating low-cost electronic devices via simple solution processes, thermal evaporation, inkjet printing, stamping, etc. M. Baldo, M. Deutsch, P. Burrows, H. Gossenberger, M. Gerstenberg, V. Ban, and S. Forrest, Adv. Mat. 10, 1505, (1998); and F. Garnier, R. Hajlaoui, A. Yassar, and P. Srivastava, Science 265, 1684 (1994). Other attributes of organic materials, particularly polymeric materials, include compatibility with flexible substrates, mechanical durability, and diversity of the chemical structure. Electrical bistable phenomena in organic thin films has been a subject of interest for quite some years now. H. Carchano, R. Lacoste, and Y. Segui, Appl. Phys. Lett. 19, 414, (1971); R. S. Potember, T. O. Poehler, and D. O. Cowman, Appl. Phys. Lett. 34, 405, (1979); L. P. Ma, J. Liu, and Y. Yang, Appl. Phys. Lett. 80, 2997 (2002) incorporated by reference herein; L. P. Ma, S. M. Pyo, J. Y. Ouyang, Q. F. Xu, and Y. Yang, Appl. Phys. Lett. 82, 1419, (2003) incorporated by reference herein; and A. Bandyopadhyay, and A. J. Pal, Appl. Phys. Lett. 84, 999, (2004). There remains a need for thin film memory elements that can be used to replace the sophisticated inorganic memory devices. Organic electron donor and acceptor materials have been used for preparing organic composite thin films. Charge transfer may occur between molecules after applying a voltage pulse and electrical bistability is observed in the composite film. W. Xu, G. R. Chen, R. J. Li, and Z. Y. Hua, Appl. Phys. Lett. 67, 2241, (1995); and L. P. Ma, W. J. Yang, Z. Q. Xue, and S. J. Pang, Appl. Phys. Lett. 73, 850, (1998), incorporated by reference herein. However, most of the organic thin films are fabricated by thermal evaporation in high vacuum and the requirements for the evaporation conditions are very strict. Hence, there is a need to develop a process with easily controlled parameters.

### SUMMARY

Further objectives and advantages will become apparent from a consideration of the description, drawings, and examples.

An electronic or electro-optic device according to an embodiment of this invention has a first electrode, a second electrode spaced apart from the first electrode, and an organic composite layer disposed between the first electrode and the second electrode. The organic composite layer is composed of an electron donor material, an electron acceptor material, and a polymer matrix material. The organic composite layer exhibits substantial bistability of an electrical property.

An organic-composite material for an electronic or electro-optic device is composed of an electron acceptor material, an electron donor material, and a polymer matrix material. The organic-composite material exhibits substantial bistability in an electrical property.

A method of storing and retrieving information includes applying a first voltage between first and second electrical leads having a layer of an organic composite material disposed therebetween. The first voltage causes a change in an electrical property state in at least a portion of the layer of organic composite material. The method also includes applying a second voltage to the first and second electrical leads and measuring an electrical current between the first and said second electrical leads, and determining an information storage state based on the measured electrical current.

### BRIEF DESCRIPTION OF THE DRAWINGS

The invention is better understood by reading the following detailed description with reference to the accompanying figures in which:

FIG. 1 is a schematic illustration of an organic memory device according to an embodiment of the current invention. Chemical structures of organic materials that can be used are also shown.

FIG. 2 shows an atomic force microscope (AFM) micrograph image showing surface topography of the organic composite film.

FIG. 3 shows I-V curves of a device according to an embodiment of the current invention having structure Al/PS:PCBM:TTF/Al. (a), (b) and (c) represent the first, second, and third bias scans, respectively. The arrow in the figure indicates the voltage-scanning direction.

FIG. 4 shows write-read-erase cycles for the device Al/(Polystyrene:TTF:PCBM)/Al according to an embodiment of this invention. The top and bottom curves are the applied voltage and the corresponding current response, respectively. “1” and “0” in the bottom figure indicate the device in the high and low conductivity states, respectively.

FIG. 5 shows retention characteristics of the organic memory device of FIG. 3 in ON and OFF states under a constant bias (0.5V) in vacuum.

FIG. 6 shows typical frequency dependence of capacitance of the device of FIG. 3 in both ON-state and OFF-state.

FIG. 7 shows the analysis of I-V characteristics for the device of FIG. 3 at (a) the high conductivity state (b) the low conductivity state.

FIG. 8 shows UV-Vis spectra of (a) TTF (b) PCBM (c) PCBM and TTF in 1,2-dichlorobenzenic.

### DETAILED DESCRIPTION

In describing embodiments of the present invention illustrated in the drawings, specific terminology is employed for the sake of clarity. However, the invention is not intended to be limited to the specific terminology so selected. It is to be understood that each specific element includes all technical equivalents which operate in a similar manner to accomplish a similar purpose.

According to an embodiment of this invention, electrical bistability in a two-terminal structure is provided with an organic-composite thin film sandwiched between metal electrodes. The thin film, may include polystyrene as the matrix, methanofullerene [6,6]-Phenyl C61-Butyric acid Methyl ester (PCBM) as an organic electron acceptor and tetrathiafulvalene (TTF) as an organic electron donor that can be formed by solution process. The polystyrene can be replaced by other polymers, such as poly(methyl methacrylate), poly(vinyl acetate), poly(ethyl methacrylate), poly(4-vinylpyridine), polyvinylpyrrolidone, poly(allylamine), poly(acrylamide), poly(9-vinylcarbazole), polyacenaphthylene, poly[2-methoxy, 5-(2′-ethyl-hexyloxy)-p-phenylene-vinylene], polyfluorene, polyaniline and polythiophene. In addition, TTF can be replaced by other electron donors, such as tetraselenafulvalene, hesamethyltetrathiafiilvalene, hexamethyltetraselenafiilvalene, 4,4′,5,5′,6,6′,7,7′-octahydrodibenzotetrafulvalene, 2,5-bis(1,3-dithiol-2-ylidene)-1,3,4,6-tetrathiapentalene, bis(ethylenedithio)tetrathaifulvalene, bis(methylenedithio)tetrathiafulvalene, tetramethyltetrathiafulvalene, tetramethyltetraselenafulvalene, dimethyl(ethylenedithio)-diselenadithiafulvalene, methylenedithiotetrathiafulvalne, tetrathioanthracene, 2,3-dimethyltetrathioanthracence, tetrawselenoanthracence, 2,3-dimethyltetraselenoanthracene, copper phthalocyanine (CuPc), zinc (II) phthalocyanine (ZnPc), ferrocence and copper (II) 2,9,16,23-tetra-tert-butyl-29H, 31H-phthalocyanine, and PCBM also can be replaced by other electron acceptors, such as tetracyanoquinodimethane, tetracyanoethylene, 1,2,3,4,5,6-tetrafluobenzen, p-chloranil, 2,5-dimethyl-N,N-dicyanoquinone diimine, dichlorodicyanobenzoquinone, tetracyanonaphthquinodimethane, 8-hydroquinone, fullerenes (including C60, C70, C76, C78, C84), fullerenols, N-ethyl-polyamino-fullerene, N-methyl-fulleropyrrolidine, and methanofullerene [61]-carboxylic acid. However, general concepts of this invention are not limited to only the above-noted materials. The device according to an embodiment of the invention exhibits repeatable electrical transition between two states with a difference in conductivity of three orders of magnitude. The device according to this embodiment of the invention shows fast switching response between the two states and nonvolatile behavior at either state for several weeks. The two states of this device can be precisely controlled by applying an appropriate voltage pulse several times without any significant device degradation. Therefore, this device can be used as a low-cost, high density, nonvolatile organic memory element, particularly when stacked multilayer memory cells are formed. The switching mechanism is attributed to the electric-field induced charge transfer between PCBM and TTF in the composite film.

In accordance with an embodiment of the present invention, we provide an electric field induced current-controlled memory device using an organic composite thin film that is composed of an electron donor and an acceptor in a polymer matrix. The electrical bistability effect occurs in a two-terminal structure with an organic composite film, prepared by an easy solution process, sandwiched between two metal electrodes.

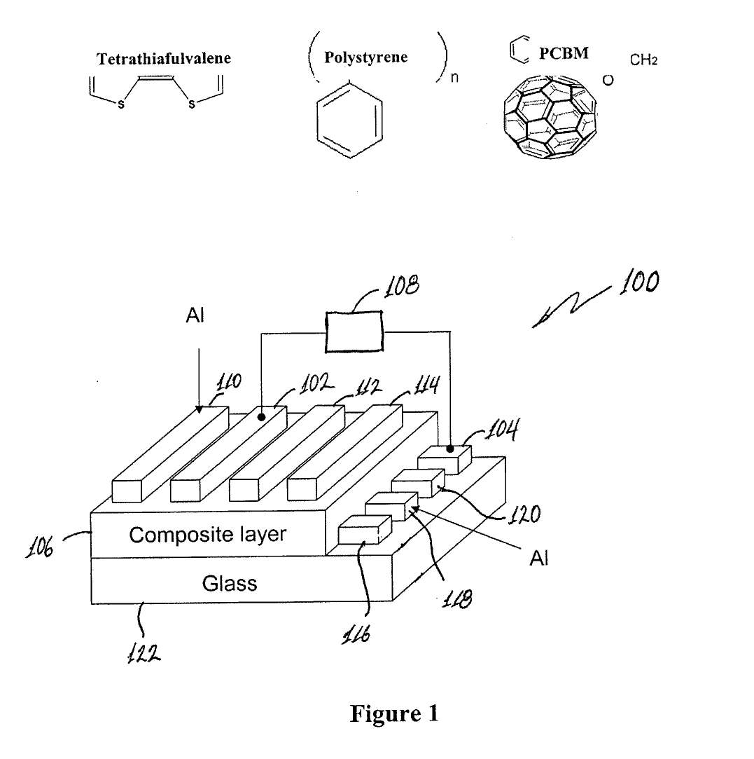

FIG. 1 is a schematic illustration of an electronic device 100 according to an embodiment of this invention. A first electrode 102 and a second electrode 104 are spaced apart with an organic-composite material 106 disposed therebetween. The organic-composite material may be a thin film layer in some embodiments of this invention. The electrodes 102, 104 may be selected from any suitable electrically conductive material for the particular application. The examples discussed in this specification include aluminum electrodes. However, the electrodes are not limited to just aluminum. The composite layer 106 comprises an electron donor material, an electron acceptor material, and a polymer matrix material. The organic composite layer 106 exhibits bistability in an electrical property. A voltage applied between electrodes 102 and 104 by an input voltage source 108 can cause a change in an electrical property of the organic-composite layer 106, depending on the applied voltage. An applied electric field will be most intense in the region where the electrodes 102 and 104 come closest together. Consequently, when one applies a voltage to electrodes 102 and 104 it can cause a change in an electrical property of the organic-composite material 106 proximate a region of smallest distance between the electrodes 102 and 104 while not changing the electrical property away from that proximate region.

The electronic device 100 according to this embodiment of the invention may also include a plurality of electrodes 110, 112 and 114 that are substantially parallel with the first electrode 102 and arranged substantially in a first layer of a plurality of electrodes. Similarly, a plurality of electrodes 116, 118 and 120 may be provided and arranged substantially parallel to the second electrode 104 to form a second layer of a plurality of electrodes. Although FIG. 1 illustrates four electrodes in each of the first and second layers of electrodes, the invention is not limited to any particular number. Furthermore, a device may include stacks of structures such as the electronic device 100. The first layer of a plurality of electrodes 110, 112, 114 and 102 and the second layer of a plurality of electrodes 116, 118, 120 and 104 provide a plurality of regions that are addressable at regions around where two electrodes come closest together. The plurality of electrodes 116, 118, 120 and 104 may be deposited on a substrate 122. The layer of organic-composite material 106 may be deposited on the substrate 122 and the first plurality of electrodes 116, 118, 120 and 104. The substrate 122 may be selected from materials according to the desired application. One may select the substrate to be an electrically nonconductive material, or combinations of electrically nonconductive materials. For example, it may be selected to be a glass substrate.

### EXAMPLE

Examples of chemical structures of the materials of the device of the embodiment of FIG. 1 are indicated in FIG. 1. The device fabrication procedure involves deposition of aluminum (Al) 0.2 mm in width and 75 nm in thickness on thoroughly cleaned glass substrates to form the bottom electrode by thermal evaporation under vacuum (below 6×10⁻⁶ Torr) in this example. Before spin-coating the composite layer, the substrates were exposed to UV-ozone treatment for 15 min. Then, the polymer film was formed by spin-coating 1,2-dichlorobenzenic solution of 1.2 wt. % polystyrene and 0.8 wt. % TTF and 0.8 wt. % PCBM. Good results have been obtained by using amounts of electron acceptor (PCBM) and electron donor (TTF) to be about the same. However, the relative amounts may vary. In addition good results were obtained using weight ratios of polymer matrix (PS):electron acceptor (PCBM):electron donor (TTF) in a range of about 1:1:1 to 10:1:1.

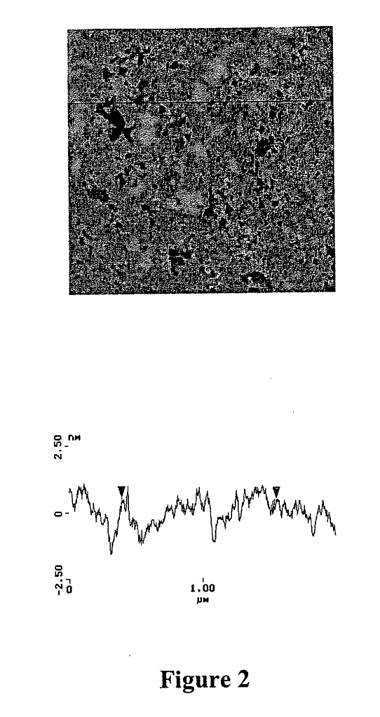

The deposited film was thermally annealed at 80° C. for 30 min. The thickness of the organic film was about 50 nm. The surface of the organic film was investigated by atomic force microscopy (AFM) and the surface scans are shown in FIG. 2. The figure shows a uniform surface with 5 Å root-mean-square roughness. Finally, 75 nm of Al was deposited as the top electrode resulting in the Al/Organic composite layer/Al sandwich structure of the memory cells according to an embodiment of the invention. The thicknesses of the organic layer and the metal electrodes were calibrated with Dektak 3030 thickness profilometer. The active device area, which is defined as the cross-section of the bottom and top electrode, was 0.2×0.2 mm². The current-voltage (I-V) characteristics of the devices were measured with a Hewlett Packard 4155B semiconductor analyzer. The capacitance measurements were carried out with a HP 4284A Precision LCR Meter. The write-read-erase cycles were measured by a programmable Keithley 2400 source meter and recorded with a four-channel oscilloscope (Tektronix TDS 460A). All the electrical measurements were performed in a vacuum lower than 1×10⁻⁴ Torr at the room temperature.

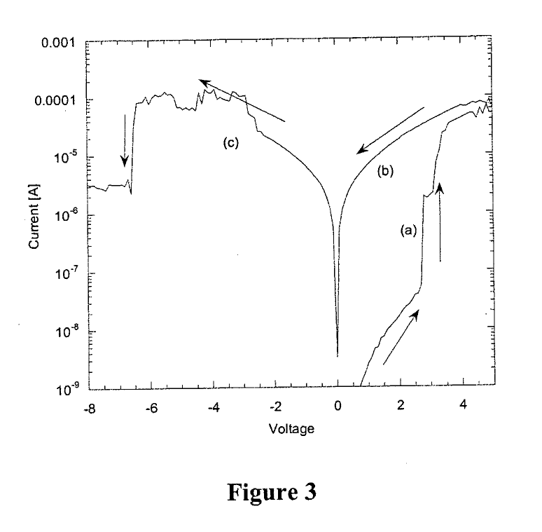

Typical I-V characteristics of bistable devices according to this embodiment of the invention are shown in FIG. 3. The devices exhibit two states of different electrical conductivity at the same voltage. During the first bias scan (curve (a)), low current was observed for the devices in bias range from 0V to 2.6V. A sharp increase in the current, from 10⁻⁷ A to 10⁻⁴ A, took place at around 2.6V indicating the transition of the devices from a low conductivity state (OFF state) to a high conductivity state (ON state). After the transition, the devices remained in that state even after the bias was removed, as shown in the subsequent voltage scan (curve (b)). The ratio of the difference in conductivity between two states was more than three orders of magnitude. The low conductivity state can be recovered by simply applying either a large positive voltage pulse or a negative voltage pulse. FIG. 3 (curve(c)) shows that the current suddenly dropped from 10⁻⁴ A to 10⁻⁶ A at −6.5V. In addition, the devices in the low conductivity state could be turned to the high conductivity state by a pulse of 5V with a width smaller than 100 ns. Also, the high conductivity state could be turned to a low conductivity state by a pulse of −9V with a width smaller than 100 ns.

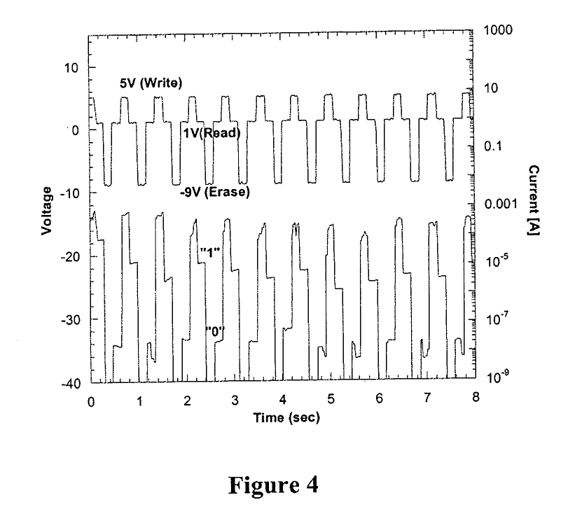

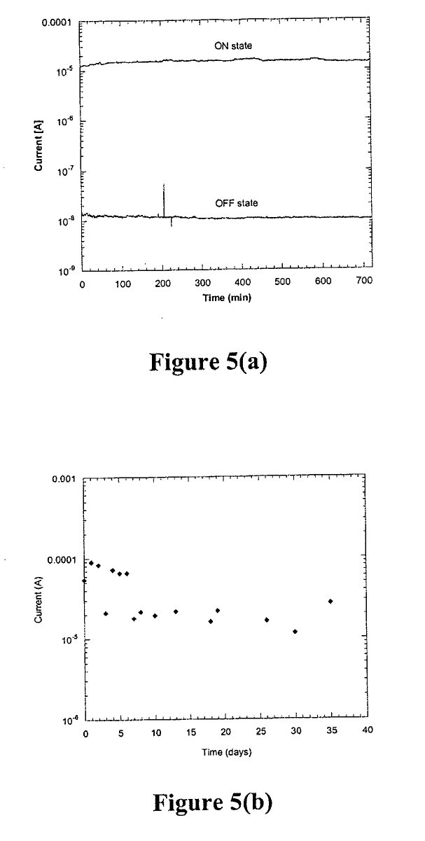

The electrical switching between low and high conductivity states was performed numerous times. A voltage pulse of 5V can induce the device to the high conductivity “1” state. This “1” state can be read by a pulse of 1 V with a current of ˜10⁻⁵ A. A negative bias of −9V can erase this “1” state to the low conductivity “0” state. The “0” state can be detected by a pulse of 1V with a current of ˜10⁻⁸ A. The electrical bistability of this device can be precisely controlled by applying an appropriate voltage pulse numerous times without any significant device degradation. The precisely controlled write-read-erase cycles were conducted on our memory devices with good rewritable characteristics as shown in FIG. 4. Moreover, once the device switches to either state it remains in that state for a prolonged period of time. The stability of the devices under stress was measured in the continuous bias condition. A constant voltage (0.5V) was applied to the device in the Off and On state and the current recorded at different times. As can be seen from FIG. 5(a), there is no significant degradation of the devices in both Off and On states even after 12 hours of continuous stress test. In addition, the retention ability was tested by leaving several devices in the high conductivity state without applying bias under a nitrogen environment. FIG. 5(b) shows that once we wrote an ON-state, the devices remained in that state for several days to weeks. These write-read-erase cycles and the duration test demonstrated that such a device could be used as a nonvolatile memory device.

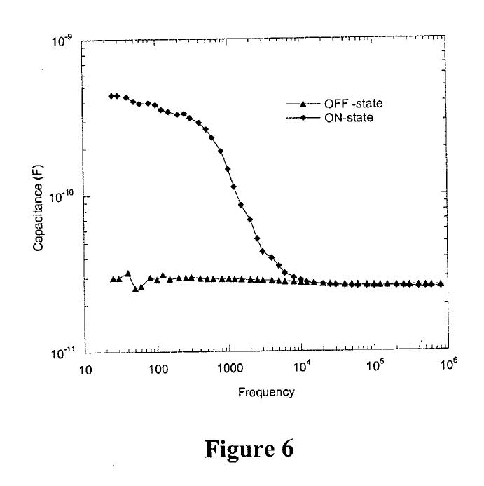

Electrical transitions have been observed previously in some polymer films, and the mechanism was attributed to the formation of conductive filaments between two metal electrodes under a high electric field. R. S. Potember, T. O. Poehler, and D. O. Cowman, Appl. Phys. Lett. 34, 405, (1979); and H. K. Henish, and W. R. Smith, Appl. Phys. Lett. 24, 589, (1974). Alternating-current impedance studies, from 20 to 106 Hz, indicate that the electronic transitions in our device are different from dielectric breakdown found in polymer films. We observed the capacitance was lowered by about an order of magnitude for the device with polystyrene film after the breakdown. However, we have observed the frequency dependence of the capacitance of our device in the ON-state and the OFF-state, as shown in FIG. 6. In the frequency range of 10⁴-10⁶ Hz the capacitance remained almost constant in both states. This suggests that the capacitance is not affected by the space charge, but determined by the dielectric constant of the bulk material between the two electrodes. In the low-frequency region (below 10⁴ Hz) the capacitance in the ON-state increased dramatically with decreasing frequency, whereas, there was little increase in the OFF-state. Polystyrene acts as an inert matrix for TTF and PCBM, and does not play a role in the electronic transition. The capacitance difference between the two states indicates that the charge carriers are generated within the composite film under an electrical field. However, there is a possibility that when PS is replaced by a conjugated polymer (such as poly(2-methoxy-5-(ethylhexyloxy)-1,4-phenylenevinylene) or polyfluorene) other phenomena might be observed, for example, a light emitting memory cell (in two terminal device), or a permanent on transistor (in three terminal device).

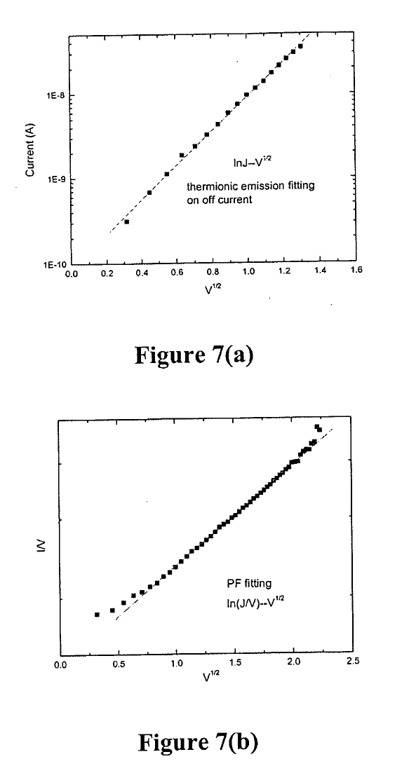

The device according to this embodiment of the invention exhibits a nonlinear relationship between current and applied electric field before and after the electrical transition. The conduction mechanism for Al/(PS:PCBM:TTF)/Al in the low conductivity state may be due to the presence of a small amount of impurity or hot electron injection. The Log (I) vs. V^{1/2} plot in the voltage range from 0 to 1.7V before the electrical transition shows linearity, as shown in FIG. 7(a). Such linearity suggests that the conduction process can be explained by Schottky emission behavior. A linear relation was observed for Log (I/V) vs. V^{1/2} plot for the device after electrical transition. The Poole-Frenkel conduction mechanism is probable for the device in the high conductivity state, as shown in FIG. 7(b). This Poole-Frenkel emission was further confirmed by using electrodes of dissimilar work functions, i.e. with the ITO/(PS:PCBM:TTF)/Al configuration, and symmetric I-V characteristic for both the polarities were observed. Hence, an electrical transition from the Schottky mechanism to Poole-Frenkel is induced for the device under a high electrical field.

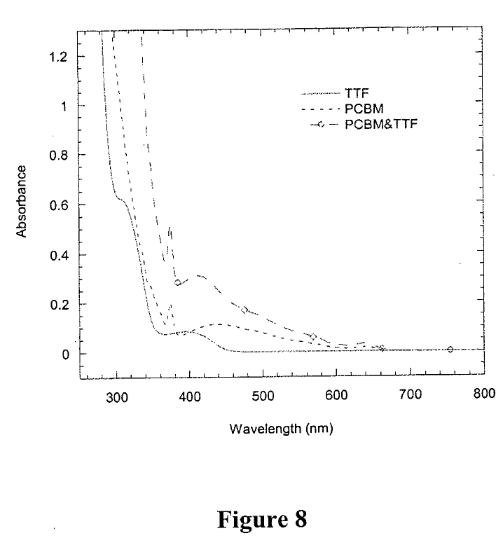

The electrical transition presumably can be attributed to an electrical-field induced charge transfer between TTF and PCBM in the film. It has already been demonstrated that TTF and PCBM can be electron donor and acceptor, respectively. M. R. Bryce, Adv. Mat. 11, 11, (1999); N. Martý´n; L. Sa´nchez, M. A. Herranz, and D. M. Guldi, J. Phys. Chem. A 104, 4648, (2000). The UV-Vis spectra didn't show significant change when we blended TTF and PCBM, as shown in FIG. 8. Therefore, prior to the electronic transition there is no interaction between TTF and PCBM. Concentration of charge carriers due to impurity in the film is quite low, so that the film has low conductivity. However, when the electrical field increases to a certain value, electrons in the HOMO of TTF may gain enough energy to transfer to PCBM. Consequently, the highest occupied molecular orbit (HOMO) of TTF becomes partially filled, and TTF and PCBM are charged positively and negatively, respectively. Therefore, carriers are generated and the device exhibits sharp increase in conductivity after the charge transfer.

In conclusion, electrical bistable devices utilizing organic materials with simplified structure have been provided by easy fabrication methods using spin coating and thermal evaporation. The control of voltage values permit devices to be designed with the required characteristics. In addition, the devices exhibit repeatable and nonvolatile electrical bistable properties. Furthermore, the devices have the potential to be stacked with several memory layers on top of each other, thus drastically increasing the density compared to nonvolatile memories based on inorganic materials. Finally, when a conjugated polymer is used to replace PS, we expect novel phenomena such as bistable LEDs and permanent-on transistors.

The embodiments illustrated and discussed in this specification are intended only to teach those skilled in the art the best way known to the inventors to make and use the invention. Nothing in this specification should be considered as limiting the scope of the present invention. The above-described embodiments of the invention may be modified or varied, and elements added or omitted, without departing from the invention, as appreciated by those skilled in the art in light of the above teachings. It is therefore to be understood that, within the scope of the claims and their equivalents, the invention may be practiced otherwise than as specifically described.

We claim:

1. An electronic or electro-optic device, comprising:
a first electrode;
a second electrode spaced apart from said first electrode; and
an organic composite layer disposed between said first electrode and said second electrode,
wherein said organic composite layer comprises an electron donor material, an electron acceptor material, and a polymer matrix material, and
wherein said organic composite layer exhibits substantially bistability of an electrical property.

2. An electronic or electro-optic device according to claim 1, wherein said electrical property of said organic composite layer changes from a first conductivity state to a second conductivity state upon the application of a voltage between said first electrode and said second electrode.

3. An electronic or electro-optic device according to claim 2, further comprising:
a plurality of electrodes arranged substantially parallel to said first electrode to form a first layer of substantially parallel electrodes;
a plurality of electrodes arranged substantially parallel to said second electrode to form a second layer of substantially parallel electrodes,
wherein said organic composite film is disposed between said first layer and said second layer of substantially parallel electrodes, and
wherein the application of a voltage between any electrode of said first layer of electrodes and any electrode of said second layer of electrodes can provide an addressable write, erase or read function.

4. An electronic or electro-optic device according to claim 1, wherein said first electrode is formed on a substrate.

5. An electronic or electro-optic device according to claim 4, wherein said substrate is a flexible material.

6. An organic-composite material for an electronic or electro-optic device, comprising
an electron acceptor material;
an electron donor material; and
a polymer matrix material,
wherein said organic-composite material exhibits substantial bistability in an electrical property.

7. An organic-composite material according to claim 6, wherein said electrical property is electrical conductivity.

8. An organic-composite material according to claim 7, wherein an applied electric field causes said electrical conductivity to transition from a first substantially stable conductivity state to a second substantially stable conductivity state.

9. An organic-composite material according to claim 6, wherein said electron donor material is selected from the group consisting of tetrathiafulvalene, tetraselenafulvalene, hesamethyltetrathiafulvalene, hexamethyltetraselenafulvalene, 4,4′,5,5′,6,6′,7,7′-octahydrodibenzotetrafulvalene, 2,5-bis(1,3-dithiol-2-ylidene)-1,3,4,6-tetrathiapentalene, bis(ethylenedithio)tetrathaifulvalene, bis(methylenedithio)tetrathiafulvalene, tetramethyltetrathiafulvalene, tetramethyltetraselenafulvalene, dimethyl(ethylenedithio)diselenadithiafulvalene, methylenedithiotetratbiafulvalne, tetrathioanthracene, 2,3-dimethyltetrathioanthracence, tetrawselenoanthracence, 2,3-dimethyltetraselenoanthracene, copper phthalocyanine (CuPc), zinc (II) phthalocyanine (ZnPc), ferrocence and copper (II) 2,9,16,23-tetra-tert-butyl-29H,31H-phthalocyanine,
said electron acceptor material is selected from the group consisting of methanofullerene [6,6]-Phenyl C61-Butyric acid Methyl ester, tetracyanoquinodimethane, tetracyanoethylene, 1,2,3,4,5,6-tetrafluobenzen, p-chloranil, 2,5-dimethyl-N,N-dicyanoquinone diimine, dichlorodicyanobenzoquinone, tetracyanonaphthquinodimethane, 8-hydroquinone, fullerenes (including C60, C70, C76, C78, C84), fullerenols, N-ethyl-polyamino-fullerene, N-methyl-fulleropyrrolidine, and methanofullerene [61]-carboxylic acid, and
said polymer matrix material is selected from the group consisting of polystyrene, poly(methyl methacrylate), poly(vinyl acetate), poly(ethyl methacrylate), poly(4-vinylpyridine), polyvinylpyrrolidone, poly(allylamine), poly(acrylamide), poly(9-vinylcarbazole), polyacenaphthylene, poly[2-methoxy, 5-(2′-ethyl-hexyloxy)-p-phenylene-vinylene], polyfluorene, polyaniline and polythiophene.

10. An organic-composite material according to claim 6, wherein said electron acceptor material is PCBM, said electron donor material is TTF, and said polymer matrix is polystyrene.

11. An organic-composite material according to claim 10, wherein said PCBM, said TTF and said polystyrene are in a ratio within the range of ratios of about 1:1:1 to 10:1:1.

12. A method of storing and retrieving information, comprising:
applying a first voltage between first and second electrical leads having a layer of an organic composite material disposed therebetween;
said first voltage causing a change in an electrical property state in at least a portion of said layer of organic composite material;
applying a second voltage to said first and second electrical leads and measuring an electrical current between said first and said second electrical leads; and
determining an information storage state based on said measured electrical current.

13. A method of storing and retrieving information according to claim 12, further comprising applying a third voltage between said first and second electrical leads to cause at least a portion of said layer of organic composite material to change said electrical property substantially back to an initial electrical property state of said layer of organic composite material.
